(19) United States
(12) Patent Application Publication
(10) Pub. No.: US 2015/0270381 A1
(43) Pub. Date: Sep. 24, 2015

(54) HETEROSTRUCTURE FIELD EFFECT TRANSISTOR HAVING HIGH EFFICIENCY AND METHOD OF PREPARING THE SAME

(71) Applicant: INDUSTRIAL COOPERATION FOUNDATION CHONBUK NATIONAL UNIVERSITY, Jeollabuk-do (KR)

(72) Inventors: InHwan LEE, Jeollabuk-do (KR); DaeWoo JEON, Jeollabuk-do (KR)

(73) Assignee: INDUSTRIAL COOPERATION FOUNDATION CHONBUK NATIONAL UNIVERSITY, Jeollabuk-do (KR)

(21) Appl. No.: 14/636,714

(22) Filed: Mar. 3, 2015

(30) Foreign Application Priority Data
Mar. 4, 2014 (KR) 10-2014-0025270

(51) Int. Cl. H01L 29/778; H01L 29/20; H01L 29/423; H01L 29/201; H01L 29/15; H01L 21/02; H01L 29/66; H01L 29/205

(52) U.S. Cl. CPC H01L 29/7787; H01L 29/66462; H01L 29/2003; H01L 29/205; H01L 29/201; H01L 29/155; H01L 21/0254; H01L 21/02645; H01L 29/42376

(57) ABSTRACT

A high-efficiency heterojunction filed effect transistor in which a gate electrode area is formed to the direction of a drain electrode on nitride-based buffer layers with a low dislocation density to exhibit a high breakdown voltage, and its preparation method.

The heterojunction field effect transistor according to the present invention minimizes dislocations in a device and provides a high breakdown voltage by forming a gate electrode area to the direction of a drain electrode on the top of the wing area that is on the far side opposite to one that includes the coalescence boundary of the wing area with a lower dislocation density in the buffer layer.

### TECHNICAL FIELD

The present invention relates to a high-efficiency heterojunction field effect transistor and its preparation method, and more specifically to a high-efficiency heterojunction filed effect transistor in which a gate electrode area is formed to the direction of a drain electrode on nitride-based buffer layers with a low dislocation density to exhibit a high breakdown voltage, and its preparation method.

### BACKGROUND ART

Telecommunications technologies rapidly evolve all around the world for high-speed, large-capacity transmission led by ICT that is also develops fast. Among other things, high-speed and high-power electronic devices have been increasingly demanded to meet the requirements in the information superhighway in micrometer and millimeter wavebands as demand sharply grows, in wireless communications, for such fields as personal mobile phone, satellite communication, military radar, broadcasting communication, communication repeater and the like.

GaN-based nitride semiconductors show superior physical properties including a wide energy gap, high thermal and chemical stability, a high saturated electron velocity that amounts to about 3×10⁷ cm/sec, etc., which is adequate for their application to optoelectronic devices and high-frequency, high-power electronic devices as well, internationally and widely promoting relevant researches about them. Those electronic devices GaN-based nitride semiconductors, especially, are used in boast diverse merits, inter alia, a high breakdown electric field that amounts to about 3×10⁶V/cm, a high maximum current density, stable high-temperature behaviors, a high thermal conductivity and the like. HFET (heterojunction field effect transistor) devices that exploit an AlGaN/GaN heterojunction have a significant band-discontinuity at their junction interface, which induces a higher concentration of electrons at the junction and further increases their electron mobility. Such a heterojunction between materials with different band gaps, e.g. AlGaN/GaN, induces along the junction interface 2DEG (2-dimensional electron gas) to forward the device properties including electron drift velocity, power density and the like with reference to conventional MOSFETs. The 2DEG induced at the AlGaN/GaN interface acts as a channel. GaN thin film is to be well manufactured to a band-pass filter that may operate at a few GHz or more because it has a high surface acoustic wave velocity and excellent temperature stability, and carries Piezoelectric effect-derived polarization.

GaN-based nitride semiconductors grow on a sapphire substrate mostly via MOCVD (metal-organic chemical vapor deposition) or MBE (molecular beam epitaxy) techniques. Sapphire substrates and GaN-based nitride semiconductors, however, are considerably different in terms of their lattice constant and coefficient of thermal expansion, which renders it very difficult for a single crystal to grow and which explains why a nitride-based semiconductor may contain, upon growing on a sapphire substrate, many lattice defects.

FIG. 1 describes a cross-sectional view of an existing nitride-based HFET. As illustrated in FIG. 1, an HFET 10 includes a GaN low-temperature buffer layer 12, a semi-insulating GaN layer 13 and a high-concentration AlGaN layer 14, all of which are consecutively stacked on a sapphire substrate 11. On the AlGaN layer are aligned 14 a gate 15, a source 16 and a drain 17. Such an existing nitride-based HFET structure may contain many lattice defects including dislocations due to the difference of the lattice constant and coefficient of thermal expansion between the sapphire substrate 11 and the GaN semiconductor. Those dislocations generated degrade the crystal quality and, consequently, the electric properties of nitride-based HFETs.

### DISCLOSURE

### Technical Problem

Accordingly, the present invention provides a heterojunction field effect transistor of which dislocations, that may be caused by the lattice mismatch between a sapphire substrate and the crystal, are abated to ameliorate the electric properties thereof.

In addition, the present invention provides a heterojunction field effect transistor that ameliorates breakdown voltage properties and lowers leakage current.

### Technical Solution

In order to achieve the objectives aforementioned, an embodiment of the present invention it to provide a heterojunction field effect including an insulating substrate;

nitride-based buffer layers, formed on the substrate, that has a wing area with lower dislocation density and a seed area with a higher dislocation density;

a GaN layer formed on the buffer layers;

an AlGaN layer formed on the GaN layer; and

a source electrode, a drain electrode and a gate electrode between the source and drain electrodes, all of which are formed on the AlGaN wherein,

if applying voltage to the gate electrode aforementioned, a gate electrode area, to which a relatively higher voltage is applied, to the direction of the drain electrode is formed on the top of the wing area that is on the far side opposite to one that includes the coalescence boundary of the wing area aforementioned, where the gate electrode area has a length of 0.1 to 1 μm, preferably, 0.2 to 0.5 μm.

Another embodiment of the present invention provides a preparation method of a heterojunction filed effect transistor including a phase that forms GaN buffer layers on a substrate;

a phase that forms a GaN layer on the GaN layer;

a phase that forms an AlGaN layer on the GaN layer; and

a phase that forms a source electrode, drain electrode and a gate electrode on the AlGaN layer wherein

the phase aforementioned that forms the GaN buffer layer includes a phase that forms a seed GaN layer on the substrate, a phase that deposits an SiO₂ layer on the seed GaN layer prior to patterning by selectively etching the SiO₂ layer and another phase that forms, via the GaN layer regrowth, a seed area that grows vertically and a wing area, that laterally overgrows on the upper side of the SiO₂ patterned; and,

in the phase aforementioned that forms the electrodes, the gate electrode area to the direction of the drain electrode is formed on the top of the wing area that is on the far side opposite to one that includes the coalescence boundary of the wing area that has been overgrown.

Yet another embodiment of the present invention provides a preparation method of a heterojunction field effect transistor including a phase that forms GaN buffer layers on a substrate;

a phase that forms a GaN layer on the GaN buffer layer;

a phase that forms an AlGaN layer on the GaN layer; and

a phase that forms a source electrode, drain electrode and gate electrode on the AlGaN layer wherein

the phase aforementioned that forms the GaN buffer layer includes a phase that forms a seed GaN layer on the substrate prior to patterning by selectively etching the seed GaN layer and the substrate underneath the seed GaN layer and another phase that forms, via the GaN layer regrowth, a wing area that laterally overgrows and a seed area that vertically grows; and

in the phase aforementioned that forms the electrodes, the gate electrode area to the direction of the drain electrode is formed on the top of the wing area that is on the far side opposite to one that includes the coalescence boundary of the wing area that has been overgrown.

### Advantageous Effects

A heterojunction field effect transistor according to the present invention minimizes dislocations in a device and provides a high breakdown voltage by forming a gate electrode area to the direction of a drain electrode on the top of the wing area that is on the far side opposite to one that includes the coalescence boundary of the wing area with a lower dislocation density in the buffer layer.

### DESCRIPTION OF DRAWINGS

FIG. 1 is a cross-sectional view of an existing nitride-based HFET.

FIG. 2 is a cross-sectional view of a heterojunction field effect transistor according to an embodiment of the present invention.

FIG. 3 is a cross-sectional view of a heterojunction field effect transistor according to another embodiment of the present invention.

FIG. 4 is a cross-sectional view of a heterojunction field effect transistor according to yet another embodiment of the present invention.

FIG. 5 illustrates a preparation method of the heterojunction field effect transistor of FIG. 2.

FIG. 6 illustrates a preparation method of the heterojunction field effect transistor of FIG. 4.

FIG. 7 illustrates photographs of the dislocations in the seed area and wing area.

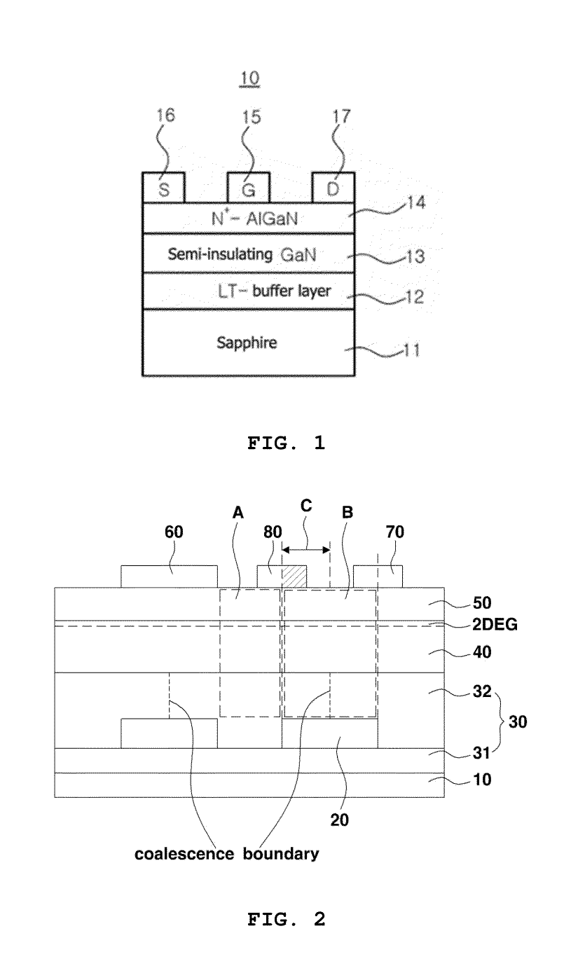

### BEST MODE

The present invention will be entirely achieved with reference to the following description which is illustrated in the accompanying drawings. The following description must be interpreted as delineating preferred embodiments of the present invention, not to limited thereto. In addition, the accompanying drawings are provided for the purpose of demonstration of the present invention. Therefore, the dimensions of the drawings including thickness, height and the like may be exaggerated when compared with those of real layers and the actual meaning of which may be properly apprehended on the basis of the specific intent of relevant statement to be mentioned.

The layered structures referred to this Specification must be interpreted as providing an example, but not to be limited thereto.

The phrases, “on (the top side)”, “on the (far) side” and the like referred to this Specification may be introduced to provide any concept of a relative location. However, a certain component or layer may directly exist on the layer referred to, or a certain layer (or interlayer) or component may be included or exist between those two layers. Furthermore, a certain layer or component may exist on the layer referred to from above but not entirely cover the surface of the layer referred to, especially in case that the surface has 3-dimensional geometry. Therefore, those phrases aforementioned may be interpreted as providing a concept of relative location unless otherwise specified by means of an expression of “directly.” Similarly, the phrases of “on the bottom side”, “on the lower side” or “underneath” may be understood as providing a concept of relative location regarding a specific layer (or component) and another layer (or component).

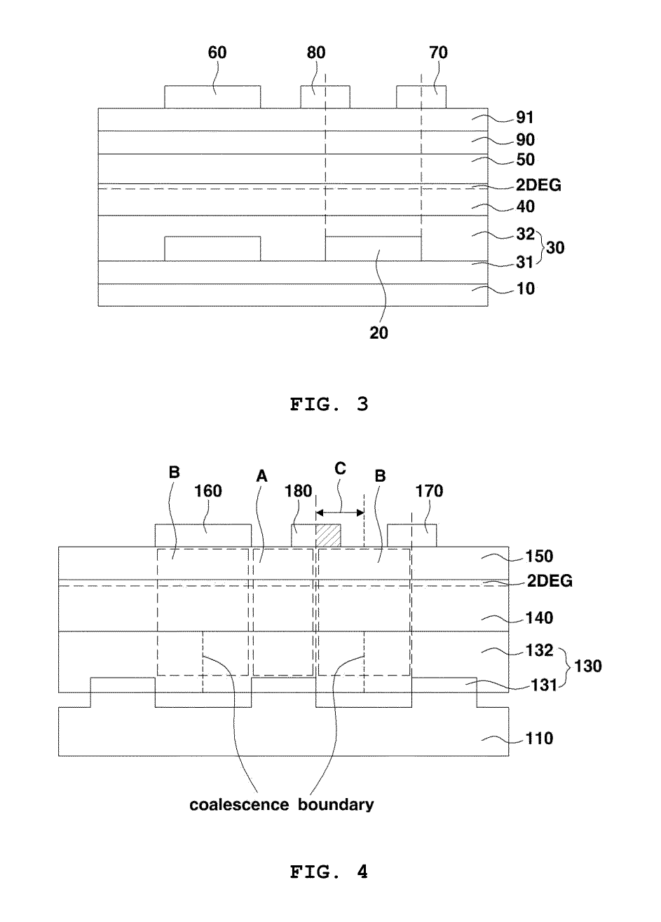

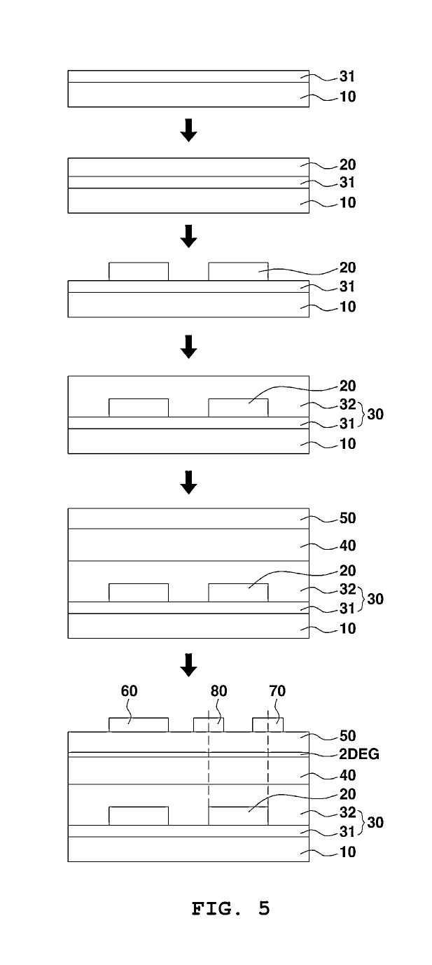

FIG. 2 and FIG. 3, respectively, are cross-sectional views of a heterojunction field effect transistor according to an embodiment of the present invention. FIG. 5 illustrates a preparation method of the heterojunction field effect transistor of FIG. 2. As illustrated in FIG. 2 and FIG. 5, an HFET (heterojunction field effect transistor) according to the present invention includes a substrate 10, SiO₂ pattern 20, nitride-based buffer layers 30, a GaN layer 40, an AlGaN layer 50, a source electrode 60, a drain electrode 70 and a gate electrode 80.

The substrate 10 is a substrate to grow a single crystal for semiconductors and may be selected among a sapphire and silicon substrate both sides of which have been polished.

GaN buffer layers 30 are formed on the substrate 10. The GaN buffer layers 30 include a seed GaN layer 31 and a GaN buffer layer 32 that has been regrown. A SiO₂ patterned layer 20 is formed on the seed GaN buffer layer 31. The GaN regrown buffer layer 32 is a low-defect GaN layer that has been grown in the ELOG or PENDEO mode.

With reference to FIG. 5, in order to form the GaN buffer layers, the seed GaN layer 31 is formed on the substrate 10 then the SiO₂ layer 20 is, via sputtering or E-beam technique, deposited on the seed GaN layer 31 prior to pattering the SiO₂ layer by selectively etching the SiO₂ layer by means of photolithography. More specifically, the SiO₂ layer deposited is covered with polymer via spin coating then patterned into stripes, subsequent to which the polymer is removed by using organic solvent. With reference to FIG. 2 and FIG. 5, there exists the right side of the SiO₂ layer 20 in the center of the drain electrode 70, but not limited thereto. For example, the SiO₂ layer 20 may be formed, with the drain electrode 70 fixed in terms of its location, so that the right end of the SiO₂ layer 20 is extended to the right of the center of the drain electrode 70 or the SiO₂ layer 20 in whole may be shifted to the right.

Then, the GaN layer 32 is formed in the ELOG mode on the SiO₂ layer patterned according to the technique aforementioned by means of MOCVD or HYPE. As a result of the ELOG of the GaN layer 32, a seed area A vertically grows and a wing area B laterally overgrows on the top of the SiO₂ patterned. The GaN layer 32 vertically grows with the seed GaN layer 31 as the center then laterally overgrows over the SiO₂ layer 20 that is located on the both sides of the GaN layer 32.

The thickness of the seed GaN buffer layer 31 may in the range from 1 to 3 μm, or preferably from 2 to 3 μm while the thickness of the regrown GaN buffer layer may in the range from 4 to 6 μm, or preferably from 4 to 5 μm. It may be required for the GaN layer to laterally grow from the seed area and, at the top center of the mask area (or consequently, the wing area), fall into line with the area that has been laterally grown from the opposite flank side, which is to be called coalescence boundary, creating a clear surface without any height difference.

The thickness of the SiO₂ patterned layer 20 may in the range from 50 to 300 nm, or preferably from 50 to 100 nm.

The width of the SiO₂ patterned layer 20 may be the width of the wing area B while the width of the SiO₂ patterned layer 20 may in the range from 5 to 20 μm, or preferably from 10 to 16 μm.

The wing area B in the GaN buffer layer 30 has a lower dislocation density than that of the seed area. The wing area may have a dislocation density of 10⁶/cm² or less.

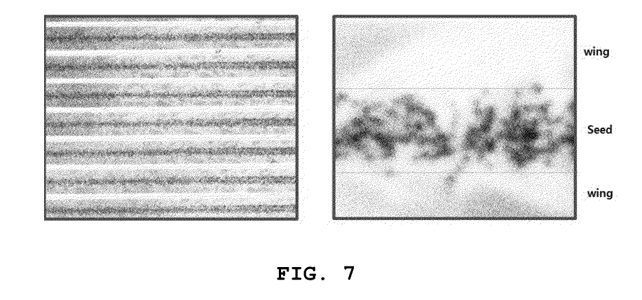

FIG. 7 illustrates photographs of the dislocations in the seed area and wing area. As shown in FIG. 7, a higher density of dislocations exists in the seed area compared with the wing area, which accounts to a very large measure, 1×10⁸/cm².

The GaN layer 40 and the AlGaN layer 50 are consecutively formed on the GaN buffer layer 30. A 2DEG layer is generated via the heterojuction between the GaN layer 40 and the AlGaN layer 50 which have a different band gap from each other. Upon signal input to the gate electrode 80, a channel is created by means of the 2DEG layer rendering current is conducted between the source electrode 60 and the drain electrode 70.

The GaN layer 40 may be an i-GaN layer unintentionally doped (UID) via MOCVD. A semi-insulating GaN layer with a high resistance may be used as the GaN layer 40.

Transistor electrodes that are source electrode 60, drain electrode 70 and gate electrode 80 are formed using metallic materials on the AlGaN layer 50.

According to the present invention, when applying voltage to the gate electrode, the gate electrode area to the drain electrode, or a part of the gate electrode opposite to the drain electrode (the area filled with hatched lines), to which a relatively higher voltage is applied, is formed on the top of the wing area that is on the far side (designated by C) opposite to one that includes that coalescence boundary with a lower dislocation density as aforementioned, where the gate electrode area has a length of 0.1 to 1 μm, preferably, 0.2 to 0.5 μm.

Consequently, the present invention provides a heterojunction field effect transistor with a high breakdown voltage by aligning the electrode to which a higher voltage is applied in the area almost without dislocations.

With reference to FIG. 3, the present invention may add a capping layer 90 to secure a low-resistance ohmic contact between the AlGaN layer 50 and transistor electrodes.

The capping layer 90 may be a superlattice layer for which AlGaN layer(s) and GaN layer(s) are stacked one after the other. The superlattice layer may be manufactured according to methods published. For example, a non-doped AlGaN layer of which Al content is 20% and height is 100 Å or less, and a silicon-doped nGaN layer of which height is 300 Å or less may be repeatedly grown one after the other.

The capping layer 90 may be formed with a total thickness of, e.g., 50 nm. On the top of the capping layer 90 is formed an n-GaN layer 91, as exploited in the superlattice layer aforementioned, with a thickness of, e.g., 20 nm.

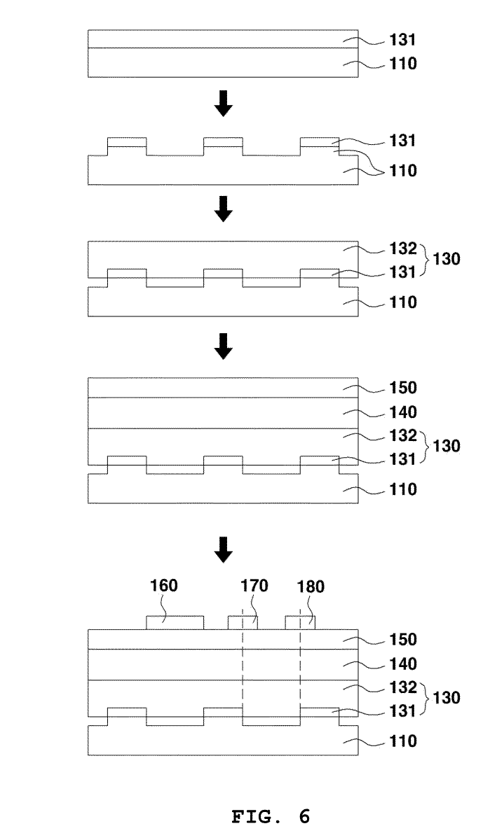

FIG. 4 is a cross-sectional view of a heterojunction field effect transistor according to yet another embodiment of the present invention. FIG. 6 is a preparation method of the heterojunction field effect transistor of FIG. 4. As illustrated in FIG. 4 and FIG. 6, a heterojunction field effect transistor according to the present invention includes a substrate 110, nitride-based buffer layers 130, an i-GaN layer 140, an AlGaN layer 150, a source electrode 160, a drain electrode 170 and a gate electrode 180.

The substrate 110 is a substrate to grow a single crystal for semiconductors and may be selected among a sapphire and silicon substrate both sides of which have been polished

GaN buffer layers 130 are formed on the substrate 110. The GaN buffer layers 130 include a GaN buffer layer 131 and a GaN buffer layer 132 that has been regrown.

With reference to FIG. 6, in order to form the GaN buffer layers, the seed layer 131 is formed on the substrate 110 then the seed GaN 131 and a certain part of substrate are selectively etched by forming a stripe pattern on the seed GaN 131. As illustrated in FIG. 6, the GaN layer 132 is formed in the PENDEO mode by means of MOCVD or HVPE on the GaN layer 131 employing a 3-dimensional structure 430 as a seed. As a result of the PENDEO of the GaN layer 132, a seed area A vertically grows and a wing area B laterally overgrows. With the reference to FIG. 4 and FIG. 6, there exists the left side of the seed GaN layer 131 in the center of the drain electrode 170, but not limited thereto. For example, the seed GaN layer 131 may be formed, with the drain electrode 170 fixed in terms of its location, so that the left end of the GaN layer 131 is extended to the right of the center of the drain electrode 70, for which the wing area B may be formed more widely.

The width of the GaN buffer layer 131 may be the width of the seed area A while the width of the wing area may be the distance between two adjacent seed GaN buffer layers 131. In other words, the width of the wing area B may be controlled according to the present invention by adjusting the width of the seed GaN layer 131. The width of the wing area may in the range from 5 to 20 μm, or preferably from 10 to 16 μm.

The thickness of the seed GaN buffer layer may be 1 to 2 μm, or preferably 1 μm while the thickness of the GaN buffer layer 132 regrown may in the range from 4 to 6 μm, or preferably from 4 to 5 μm. It may be required for the GaN layer to laterally grow from the seed area and fall into line with the area that has been laterally grown from the opposite flank side, which is to be called coalescence boundary, creating a clear surface without any height difference.

The wing area B in the GaN buffer layer 130 has a lower dislocation density than that of the seed area. The wing area may have a dislocation density of 10⁶/cm² or less.

The description provided above (or FIGS. 2, 3 and 5) may be informative regarding the GaN buffer layers 130, GaN layer 140, AlGaN layer 150, source electrode 160, drain electrode 170 and gate electrode 180.

With reference to FIGS. 4 to 6, transistor electrodes that are source electrode 160, drain electrode 170 and gate electrode 180 are formed using metallic materials on the AlGaN layer 150.

According to the present invention, when applying voltage to the gate electrode, the gate electrode area to the drain electrode, or a part of the gate electrode opposite to the drain electrode (the area filled with hatched lines), to which a relatively higher voltage is applied, is formed on the top of the wing area that is on the far side (designated by C) opposite to one that includes that coalescence boundary with a lower dislocation density as aforementioned, where the gate electrode area has a length of 0.1 to 1 μm, preferably, 0.2 to 0.5 μm.

Consequently, the present invention may provide a heterojunction field effect transistor with a high breakdown voltage by aligning the electrode to which a higher voltage is applied in the area almost without dislocations.

Regarding a heterojunction field effect transistor shown in FIG. 4, a capping layer may add a capping layer (not illustrated) to secure a low-resistance ohmic contact between the AlGaN layer 150 and the transistor electrode layer. The description provided above may be informative regarding the capping layer.

The description thus far is nothing more than an exemplification of the technical thoughts of this invention and a person skilled in the art to which this invention belongs may, not deviating from the scope of the essential features of this invention, amend and modify this example. In this perspective, the preferred embodiments demonstrated in this invention are not to restrict but to expound the technical thoughts of this invention while the scope of the technical thoughts of this invention shall not restricted within such examples. The scope of the protection for this invention should be interpreted based on the claims as follows and all the technical thoughts in the scope equivalent to that of those Claims should be comprehended to be included in the scope of the rights of this invention.

### REFERENCE NUMERALS

10; 110: substrate
20; 120: SiO₂ pattern
30; 130: nitride-based buffer layer
40; 140: GaN layer
50; 150: AlGaN layer
60; 160: source electrode
70; 170: drain electrode
80; 180: gate electrode
90: capping layer
A: seed area
B: wing area

What is claimed is:

1. A heterojunction field effect transistor comprising:
an insulating substrate;
nitride-based buffer layers, formed on the substrate, that has a wing area with lower dislocation;
density and a seed area with a higher dislocation density;
a GaN layer formed on the buffer layers;
an AlGaN layer formed on the GaN layer; and
a source electrode, a drain electrode and a gate electrode between the source and drain electrodes, all of which are formed on the AlGaN,
wherein, if applying voltage to the gate electrode aforementioned, a gate electrode area, to which a relatively higher voltage is applied, to the direction of the drain electrode is formed on the top of the wing area that is on the far side opposite to one that includes the coalescence boundary of the wing area aforementioned.

2. The heterojunction field effect transistor of claim 1, wherein the wing area has a dislocation density of 10⁶/cm² or less.

3. The heterojunction field effect transistor of claim 1, wherein the width of the wing area is in the range from 10 to 16 μm.

4. The heterojunction field effect transistor of claim 1, wherein the gate electrode has a length of 0.1 to 1 μm.

5. The heterojunction field effect transistor of claim 1, further comprising a capping layer is added to secure a low-resistance ohmic contact on the AlGaN layer.

6. The heterojunction field effect transistor of claim 3, wherein the capping layer is an AlGaN/GaN superlattice layer for which AlGaN layer(s) and GaN layer(s) are stacked one after the other.

7. A preparation method of a heterojunction filed effect transistor comprising:
a phase that forms GaN buffer layers on a substrate;
a phase that forms a GaN layer on the GaN layer;
a phase that forms an AlGaN layer on the GaN layer; and
a phase that forms a source electrode, drain electrode and a gate electrode on the AlGaN layer,
wherein the phase aforementioned that forms the GaN buffer layer includes a phase that forms a seed GaN layer on the substrate, a phase that deposits an SiO₂ layer on the seed GaN layer prior to patterning by selectively etching the SiO₂ layer and another phase that forms, via the GaN layer regrowth, a seed area that grows vertically and a wing area, that laterally overgrows on the upper side of the SiO₂ patterned; and, in the phase aforementioned that forms the electrodes, the gate electrode area to the direction of the drain electrode is formed on the top of the wing area that is on the far side opposite to one that includes the coalescence boundary of the wing area that has been overgrown.

8. A preparation method of a heterojunction field effect transistor comprising:
a phase that forms GaN buffer layers on a substrate;
a phase that forms a GaN layer on the GaN buffer layer; a phase that forms an AlGaN layer on the GaN layer; and
a phase that forms a source electrode, drain electrode and gate electrode on the AlGaN layer,
wherein the phase aforementioned that forms the GaN buffer layer comprises a phase that forms a seed GaN layer on the substrate prior to patterning by selectively etching the seed GaN layer and the substrate underneath the seed GaN layer and another phase that forms, via the GaN layer regrowth, a wing area that laterally overgrows and a seed area that vertically grows; and in the phase aforementioned that forms the electrodes, the gate electrode area to the direction of the drain electrode is formed on the top of the wing area that is on the far side opposite to one that includes the coalescence boundary of the wing area that has been overgrown.

9. The preparation method of a heterojunction field effect transistor of claim 7, wherein the wing area has a dislocation density of 10⁶/cm² or less.

10. The preparation method of a heterojunction field effect transistor of claim 7, wherein the gate electrode has a length of 0.1 to 1 μm.

11. The preparation method of a heterojunction field effect transistor of claim 7, wherein the width of the wing area is controlled by adjusting the width of the pattern width of the SiO₂ layer.

12. The preparation method of a heterojunction field effect transistor of claim 8, wherein the width of the wing area is controlled by adjusting the width of the seed GaN layer.

13. The preparation method of a heterojunction field effect transistor of claim 8, wherein the wing area has a dislocation density of 10⁶/cm² or less.

14. The preparation method of a heterojunction field effect transistor of claim 8, wherein the gate electrode has a length of 0.1 to 1 μm.
